(19) United States
(12) Patent Application Publication
(10) Pub. No.: US 2026/0143948 A1
(43) Pub. Date: May 21, 2026

(54) LIGHT-EMITTING DEVICE, DISPLAY DEVICE INCLUDING THE SAME AND ELECTRONIC DEVICE INCLUDING THE SAME

(71) Applicant: Samsung Display Co., Ltd., Yongin-si (KR)

(72) Inventor: Hyun Eok SHIN, Yongin-si (KR)

(73) Assignee: Samsung Display Co., Ltd., Yongin-si (KR)

(21) Appl. No.: 19/294,683

(22) Filed: Aug. 8, 2025

(30) Foreign Application Priority Data
Nov. 21, 2024 (KR) 10-2024-0167025

(51) Int. Cl. H10K 59/80; H10K 59/12

(52) U.S. Cl. CPC H10K 59/80523; H10K 59/1201; H10K 59/80524

(57) ABSTRACT

A light-emitting device may include: a first electrode; an intermediate layer on the first electrode, the intermediate layer including an emission layer; and a second electrode structure including: a first layer including a rare earth oxide; a second layer including an electride; and a third layer including a transparent conductive oxide, wherein the intermediate layer is between the second electrode structure and the first electrode, and wherein the first layer, the second layer, and the third layer are sequentially stacked on the intermediate layer.

### CROSS-REFERENCE TO RELATED APPLICATION

This application claims priority to Korean Patent Application No. 10-2024-0167025, filed on Nov. 21, 2024, in the Korean Intellectual Property Office (KIPO), the entire disclosure of which is incorporated by reference herein.

### BACKGROUND

### 1. Technical Field

Embodiments of the present disclosure relate to a light-emitting device, a display device including the same, and electronic device including the same. More particularly, embodiments of the present disclosure relate to a light-emitting device including an electrode and an emission layer, a display device including the same, and an electronic device including the same.

### 2. Description of the Related Art

An organic light-emitting diode (OLED) display device has a self-luminous property, and may provide improved viewing angle and contrast properties. Additionally, a high response speed and a high luminance may be provided.

The OLED display device may include an emission layer disposed between a first electrode and a second electrode. A hole transferred from the first electrode and an electron transferred from the second electrode may be recombined in the emission layer to generate an exciton. Light emission properties are implemented as the exciton is shifted from an excited state to a ground state. There is a need for improved electron generation and electron injection properties between the second electrode and the emission layer.

Information disclosed in this Background section has already been known to or derived by the inventors before or during the process of achieving the embodiments of the present application, or is technical information acquired in the process of achieving the embodiments. Therefore, it may contain information that does not form prior art that is already known to the public.

### SUMMARY

According to some embodiments of the present disclosure, a light-emitting device having improved electron transfer properties and chemical stability may be provided.

According to some embodiments of the present disclosure, a display device having improved electron transfer properties and chemical stability may be provided.

According to some embodiments of the present disclosure, an electronic device including the light-emitting device or the display device may be provided.

According to some embodiments of the present disclosure, a light-emitting device may include: a first electrode; an intermediate layer on the first electrode, the intermediate layer including an emission layer; and a second electrode structure including: a first layer including a rare earth oxide; a second layer including an electride; and a third layer including a transparent conductive oxide, wherein the intermediate layer is between the second electrode structure and the first electrode, and wherein the first layer, the second layer, and the third layer are sequentially stacked on the intermediate layer.

According to an embodiment of the present disclosure, a work function of the first layer, a work function of the second layer, and a work function of the third layer may increase in the order of the first layer, the second layer, and the third layer.

According to an embodiment of the present disclosure, the work function of the first layer may be 2 eV or more, and less than 3 eV.

According to an embodiment of the present disclosure, the work function of the second layer may be in a range from 3.0 eV to 3.5 eV.

According to an embodiment of the present disclosure, the work function of the third layer may be in a range from 4 eV to 5 eV.

According to an embodiment of the present disclosure, the first layer may include yttrium (Y) oxide or ytterbium (Yb) oxide.

According to an embodiment of the present disclosure, the electride of the second layer may include a Group II metal element.

According to an embodiment of the present disclosure, the electride of the second layer may be an amorphous calcium-aluminum containing electride.

According to an embodiment of the present disclosure, the third layer may include indium tin oxide (ITO), indium zinc oxide (IZO), zinc oxide, indium gallium zinc oxide (IGZO), or indium tin zinc oxide (IGZO).

According to an embodiment of the present disclosure, a thickness of the first layer, a thickness of the second layer, and a thickness of the third layer may increase in the order of the first layer, the second layer, and the third layer.

According to an embodiment of the present disclosure, the intermediate layer may include: an electron transfer region between the emission layer and the second electrode structure; and a hole transfer region between the emission layer and the first electrode.

According to an embodiment of the present disclosure, the electron transfer region may include an electron transport layer that includes an organic material, and the first layer of the second electrode structure is in contact with the electron transport layer.

According to an embodiment of the present disclosure, the first electrode may be configured as an anode, and the third layer of the second electrode structure may be configured as a cathode.

According to some embodiments of the present disclosure, a display device may include: a base substrate; a pixel circuit including a transistor, the pixel circuit being on the base substrate; and a light-emitting device connected to the transistor, wherein the light-emitting device includes: a first electrode; an intermediate layer on the first electrode, the intermediate layer including an emission layer; and a second electrode structure including: a first layer including a rare earth oxide; a second layer including an electride; and a third layer including a transparent conductive oxide, wherein the intermediate layer is between the second electrode structure and the first electrode, and wherein the first layer, the second layer, and the third layer are sequentially stacked on the intermediate layer in the order of the first layer, the second layer, and the third layer.

According to some embodiments of the present disclosure, an electronic device may include: the display device; a memory; and a processor configured to control an operation of the display device by executing data included in the memory.

According to an embodiment of the present disclosure, the electronic device may include virtual or augmented reality glasses, a smartphone, a tablet PC, a laptop, a TV, a desk monitor, smart glasses, a head mounted display, a smart watch, or a vehicle display.

According to some embodiments of the present disclosure, a method for manufacturing a light-emitting device may include: forming an intermediate layer on a first electrode, the intermediate layer including an emission layer; forming a rare earth metal layer on the intermediate layer; forming a second layer by depositing an electride on the rare earth metal layer while converting the rare earth metal layer into a first layer that includes a rare earth oxide; and forming a third layer on the second layer, the third layer including a transparent conductive oxide.

According to an embodiment of the present disclosure, the forming the second layer may include naturally oxidizing the rare earth metal layer.

According to an embodiment of the present disclosure, the forming the second layer may include performing a deposition process using a crystalline electride target, wherein the electride of the second layer is an amorphous electride.

According to an embodiment of the present disclosure, a work function of the first layer, a work function of the second layer, and a work function of the third layer may increase in the order of the first layer, the second layer, and the third layer.

The light-emitting device according to embodiments of some embodiments of the present disclosure may include a stacked structure of a first layer, a second layer, and a third layer having sequentially increasing work functions from an emission layer. The stacked structure may be configured as a cathode of the light-emitting device, and may provide improved electron injection properties into the emission layer.

Oxygen injection or ion collision into the emission layer or an electron transfer region may be suppressed utilizing the stacked structure, and improved electron injection properties may be implemented.

### BRIEF DESCRIPTION OF DRAWINGS

FIGS. 1 to 5 are schematic cross-sectional views illustrating light-emitting devices according to embodiments.

FIGS. 6 and 7 are schematic cross-sectional views illustrating a method of manufacturing a light-emitting device according to embodiments.

FIG. 8 is a schematic diagram illustrating a light-emitting mechanism in a light-emitting device according to embodiments.

FIGS. 9 to 11 are schematic cross-sectional views illustrating display devices according to embodiments.

FIG. 12 is an exploded perspective view illustrating an electronic device according to embodiments.

FIG. 13 is a schematic plan view illustrating an arrangement of pixels of a display device included in an electronic device according to embodiments.

FIG. 14 is a block diagram of an electronic device in accordance with an embodiment.

FIG. 15 is a schematic diagram of an electronic device in accordance with various embodiments.

### DETAILED DESCRIPTION

Hereinafter, non-limiting example embodiments of the present disclosure will be described in more detail with reference to the accompanying drawings. The same reference numerals may be used for indicating the same elements in the drawings, and repeated descriptions of the same elements may be omitted. All modifications, equivalents, and substitutes of embodiments of the present disclosure are included in the spirit and scope of the present disclosure.

In the present disclosure, it will be understood that when an element (or area, layer, or portion) is referred to as being “on,” “connected to”, or “coupled to” another element or layer, it can be directly on, connected, or coupled to the other element or layer or intervening elements or layers may be present. The terms such as “first,” “second,” “below,” “lower,” “above,” “upper,” etc., are used in a relative sense to distinguish different elements or positions, and do not specify an absolute position or an absolute order.

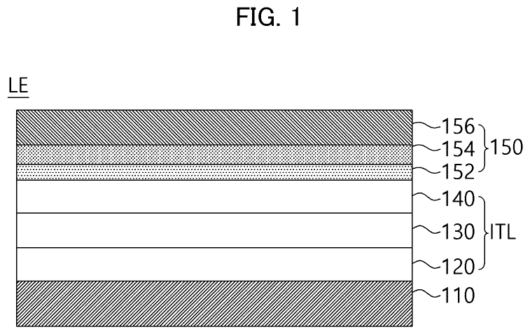

FIGS. 1 to 5 are schematic cross-sectional views illustrating light-emitting devices according to embodiments.

Referring to FIGS. 1 to 5, an light-emitting device LE may include a first electrode 110, a second electrode structure 150, and an intermediate layer ITL disposed between the first electrode 110 and the second electrode structure 150. The intermediate layer ITL may include an emission layer 130. The intermediate layer ITL may further include a hole transfer region 120 and an electron transfer region 140.

According to embodiments, the first electrode 110 may be configured as an anode, and may be configured as a pixel electrode. The first electrode 110 may include a high work function conductive material that promotes hole injection. According to embodiments, the work function of a material may refer to a minimum energy required to remove an electron from the Fermi level of the material to the vacuum level.

The first electrode 110 may be provided as a transmissive electrode. The first electrode 110 may include a transparent conductive oxide such as indium tin oxide (ITO), indium zinc oxide (IZO), zinc oxide (ZnO), indium tin oxide (ITZO), or the like.

The first electrode 110 may be provided as a translucent electrode or a reflective electrode. The first electrode 110 may include a metal selected from Ag, Mg, Cu, Al, Pt, Pd, Au, Ni, Nd, Ir, Cr, Li, Ca, LiF, Mo, Ti, W, In, Sn, and Zn, or an alloy of two or more therefrom. For example, the first electrode 110 may include Li, Ca, LiF/Ca (a stacked structure of LiF and Ca), LiF/Al (a stacked structure of LiF and Al), a mixture of Ag and Mg, or the like.

The first electrode 110 may have a single-layered structure or a multi-layered structure. For example, the first electrode 110 may have a triple-layered structure of ITO/Ag/ITO.

A thickness of the first electrode 110 may be in a range from about 700 Å to about 10,000 Å, or from about 1,000 Å to about 3,000 Å.

The intermediate layer ITL may include the emission layer 130. The emission layer 130 may include an organic light-emitting material and may include a host material. For example, the emission layer 130 may include a host material such as an anthracene derivative, a pyrene derivative, a fluoranthene derivative, a chrycene derivative, a dihydrobenzanthracene derivative, a triphenylene derivative, or the like.

The emission layer 130 may further include a dopant interacting with the above-described host. For example, the emission layer 130 may include a fluorescent dopant or a phosphorescent dopant. The emission layer 130 may include a boron-containing dopant.

In some embodiments, the emission layer 130 may include two or more types of the host material. For example, the emission layer 130 may include a hole transporting host and an electron transporting host. In this case, the emission layer 130 may include the hole transporting host, the electron transporting host, a photosensitive agent, and a dopant. According to embodiments, the hole transporting host and the electron transporting host may form an exciplex, and energy transition from the exciplex to the photosensitive agent, and from the photosensitive agent to the dopant may occur, thereby inducing light emission.

The intermediate layer ITL may further include the hole transfer region 120. The hole transfer region 120 may be disposed between the first electrode 110 and the emission layer 130.

The hole transfer region 120 may have a single-layered structure or a multi-layered structure including a plurality of layers that may include different materials from each other.

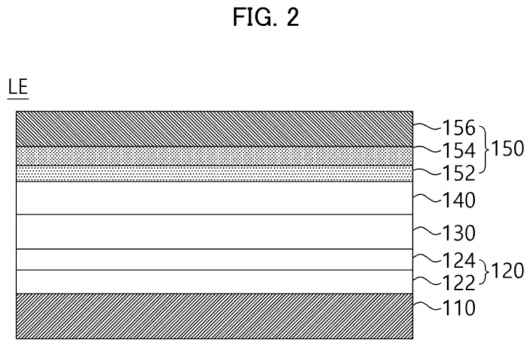

In some embodiments, as illustrated in FIG. 2, the hole transfer region 120 may include a hole injection layer 122 and a hole transport layer 124 sequentially stacked on the first electrode 110.

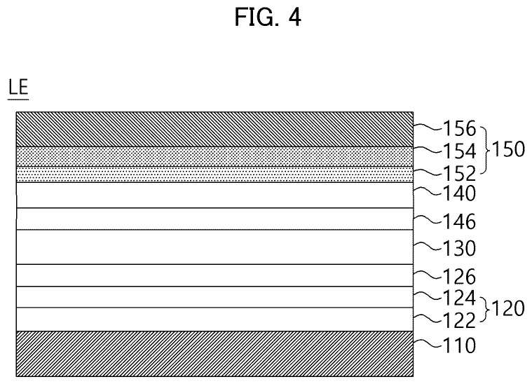

In some embodiments, as illustrated in FIG. 4, an electron blocking layer 126 may be included between the hole transfer region 120 and the emission layer 130. The electron blocking layer 126 may block movement of electrons from the electron transfer region 140 to the hole transfer region 120. Accordingly, generation of excitons in the emission layer 130 may be increased, and luminous efficiency may be further increased.

For example, the hole transfer region 120 may include m-MTDATA (4,4′,4″ [tris(3-methylphenyl)phenylamino] triphenylamine), TDATA (4,4′4″ tris(N, N-diphenylamino)triphenylamine), 2-TNATA (4,4′,4″ tris[N(2-naphthyl)-N-phenylamino]-triphenylamine), NPB(N, N′-di(naphthalene-l-yl)-N, N′-diphenyl-benzidine), TPD (N, N′-bis(3-methylphenyl)-N, N′-diphenyl-[1,1′-biphenyl]-4,4′-diamine), Spiro-TPD, Spiro-NPB, DNTPD (N1,N1′-([1,1′-biphenyl]-4,4′-diyl)bis(N1-phenyl-N4,N4-di-m-tolylbenzene-1,4-diamine), TAPC (4,4′-cyclohexylidene bis[N, N-bis(4-methylphenyl)benzenamine]), HMTPD (4,4′-bis[N, N′-(3-tolyl)amino]-3,3′-dimethylbiphenyl), TCTA (4,4′,4″-tris(N-carbazolyl)triphenylamine), PANI/DBSA (polyaniline/Dodecylbenzenesulfonic acid), PEDOT/PSS (poly(3,4-ethylenedioxythiophene)/poly(4-styrenesulfonate)), PANI/CSA (polyaniline/camphor sulfonicacid), PANI/PSS (polyaniline/poly(4-styrenesulfonate)), a phthalocyanine-based compound, a carbazole-based compound (N-phenylcarbazole, polyvinylcarbazole, etc.), a fluorene-based compound, or the like. These may be used alone or in a combination of two or more therefrom.

The above-described material may be included in at least one from among the hole injection layer 122, the hole transport layer 124, and the electron blocking layer 126.

The hole transfer region 120 may further include a charge generating material. A dopant material such as p-dopant may be used as the charge generating material, and thus conductivity of the hole transfer region 120 may be improved.

Examples of the dopant material may include a halogenated metal compound such as LiF, NaCl, CsF, RbCl, RbI, CuI, and KI; a quinone derivative such as TCNQ (tetracyanoquinodimethane), F4-TCNQ (2,3,5,6-tetrafluoro-7,7,8,8-tetracyanoquinodimethane), etc. ; a cyano-containing compound such as HATCN (dipyrazino[2,3-f: 2′,3′-h] quinoxaline-2,3,6,7,10,11-hexacarbonitrile), NDP 9(4 -[[2,3-bis[cyano-(4-cyano-2,3,5,6-tetrafluorophenyl)methylidene]cyclopropylidene]-cyanomethyl]-2,3,5,6-tetrafluorobenzonitrile), etc. ; a tungsten (W) oxide; a molybdenum (Mo) oxide, or the like. The hole transfer region 120 may include one of the dopant materials described above, or a combination thereof.

A thickness of the hole transfer region 120 may be in a range of about 100 Å to about 10,000 Å. For example, the thickness of the hole transfer region 120 may be in a range of about 100 Å to about 1,500 Å.

When the hole transfer region 120 includes the hole injection layer 122 or the hole transport layer 124, a thickness of the hole injection layer 122 may be in a range from about 100 Å to about 9,000 Å, from about 100 Å to about 3,000 Å, or from about 100 Å to about 1,000 Å. A thickness of the hole transport layer 124 may be in a range from 50 Å to about 2,000 Å, from about 100 Å to about 1,500 Å, from about 100 Å to about 1,000 Å, or from about 100 Å to about 600 Å.

In the thickness ranges described above, hole transfer properties may be enhanced even at a low voltage operation, and a life-span of the device may be further improved.

Each layer of the hole transfer region 120 may be formed by a process such as thermal deposition, vacuum deposition, spin coating, inkjet printing, laser printing, casting, laser thermal transfer, or the like.

The intermediate layer ITL may include the electron transfer region 140. The electron transfer region 140 may be disposed between the second electrode structure 150 and the emission layer 130. The electron transfer region 140 may have a single-layered structure or a multi-layered structure including a plurality of layers that may include different materials from each other.

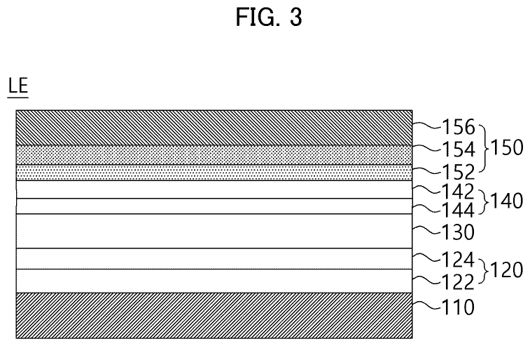

In some embodiments, as illustrated in FIG. 3, the electron transfer region 140 may include an electron injection layer 142 and an electron transport layer 144 sequentially stacked on the second electrode structure 150 in a direction toward the emission layer 130.

In some embodiments, as illustrated in FIG. 4, a hole blocking layer 146 may be included between the electron transfer region 140 and the emission layer 130. Injection of a hole from the hole transfer region 120 may be suppressed or blocked by the hole blocking layer 146. Accordingly, emission energy and luminous efficiency in the emission layer 130 may be further improved.

For example, the electron transfer region 140 may include an anthracene-based compound, Alq₃(tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (Bis(2-methyl-8-quinolinolato-N1,O8)-(1,1′-biphenyl-4-olato)aluminum), Bebq2 (beryllium bis(benzoquinolin-10-olate)), ADN (9,10-di(naphthalene-2-yl)anthracene), BmPyPhB (1,3-bis[3,5-di(pyridin-3-yl)phenyl]benzene), or the like. These may be used alone or in a combination of two or more therefrom.

The above-described material may be included in at least one layer from among the electron injection layer 142, the electron transport layer 144, and the hole blocking layer 146.

The electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof. In an embodiment, the above-described material may be included in the electron injection layer 142.

In some embodiments, the electron transfer region 140 may not include a compound or a complex including the above-described alkali metal, alkaline earth metal, and/or rare earth metal. In an embodiment, the electron injection layer 142 in FIG. 3 may be omitted. A thickness of the electron transfer region 140 may be in a range from about 100 Å to about 1000 Å, for example, from about 150 Å to about 500 Å.

When the electron transfer region 140 includes the electron injection layer 142 and the electron transport layer 144, a thickness of the electron injection layer 142 may be in a range from about 1 Å to about 100 Å, from about 1 Å to about 90 Å, or from about 5 Å to about 50 Å, and a thickness of the electron transport layer 144 may be in a range from about 10 Å to about 900 Å, from about 10 Å to about 500 Å, or from about 100 Å to about 400 Å.

In the above thickness range, electron injection and electron transport properties may be further improved without an excessive increase in a driving voltage, and stability of the electron transfer region 140 may be improved.

Each layer of the electron transfer region 140 may be formed through a process such as thermal deposition, vacuum deposition, spin coating, inkjet printing, laser printing, casting, laser thermal transfer, or the like.

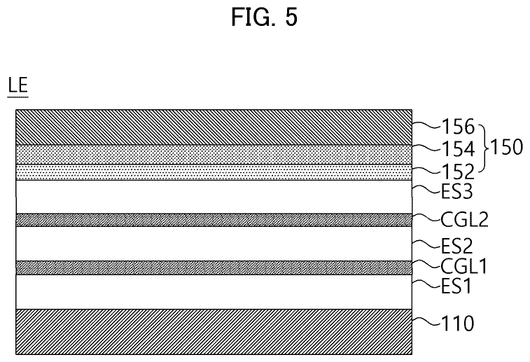

Referring to FIG. 5, the light-emitting device LE may include a plurality of light-emitting structures (e.g., a first light-emitting structure ES1, a second light-emitting structure ES2, and a third light-emitting structure ES3). Each of the light-emitting structures (e.g., the first light-emitting structure ES1, the second light-emitting structure ES2, and the third light-emitting structure ES3) may include a stacked structure of the hole transfer region 120, the emission layer 130, and the electron transfer region 140 described with reference to FIGS. 1 to 4. According to embodiments, the light-emitting device LE of FIG. 5 may be a light-emitting device having a tandem structure.

Charge generation layers (e.g., a first charge generation layer CGL1 and a second charge generation layer CGL2) may be disposed between neighboring light-emitting structures (e.g., the first light-emitting structure ES1, the second light-emitting structure ES2, and the third light-emitting structure ES3). The charge generation layers (e.g., the first charge generation layer CGL1 and the second charge generation layer CGL2) may include a p-type charge generation layer and/or an n-type charge generation layer.

The p-type charge generation layer may include a compound that may be utilized as a hole transport host such as an NPB. The p-type charge generation layer may further include a p-dopant such as TCNQ.

The n-type charge generation layer may include a compound that may be used as an electron transporting host. In an embodiment, the n-type charge generation layer may include a phenanthroline-based compound.

The charge generation layers may include a first charge generation layer CGL1 disposed between the first light-emitting structure ES1 and the second light-emitting structure ES2, and a second charge generation layer CGL2 disposed between the second light-emitting structure ES2 and the third light-emitting structure ES3.

According to embodiments, the first light-emitting structure ES1, the first charge generation layer CGL1, the second light-emitting structure ES2, the second charge generation layer CGL2, the third light-emitting structure ES3, and the second electrode structure 150 may be sequentially stacked on a top surface of the first electrode 110.

Colors emitted from the first light-emitting structure ES1, the second light-emitting structure ES2, and the third light-emitting structure ES3 may be the same or different from each other. In a non-limiting example, the first light-emitting structure ES1, the second light-emitting structure ES2 and the third light-emitting structure ES3 may include a red light-emitting layer, a green light-emitting layer, and a blue light-emitting layer, respectively, and a white light-emitting structure may be implemented through a tandem structure including the first light-emitting structure ES1, the second light-emitting structure ES2, and the third light-emitting structure ES3.

In FIG. 5, a 3-stack tandem structure in which three light-emitting structures are stacked is illustrated as an example, but the tandem structure of the light-emitting device LE of embodiments of the present disclosure are not limited to the structure illustrated in FIG. 5. For example, the tandem structure may have a 2-stack structure, a 4-stack structure, a 5 or more-stack structure.

According to embodiments of the present disclosure, the second electrode structure 150 may be disposed on the emission layer 130. The second electrode structure 150 may face the first electrode 110 with the emission layer 130 interposed therebetween. The second electrode structure 150 may be disposed on the electron transfer region 140. According to embodiments, the hole transfer region 120, the emission layer 130 (e.g., a light emission layer), the electron transfer region 140, and the second electrode structure 150 may be sequentially disposed on the first electrode 110.

As described above, the first electrode 110 may be configured as an anode, and the second electrode structure 150 may include a cathode.

The second electrode structure 150 may have a multi-layered structure. As illustrated in FIGS. 1 to 5, the second electrode structure 150 may include a first layer 152, a second layer 154, and a third layer 156 sequentially stacked on the emission layer 130. The first layer 152, the second layer 154, and the third layer 156 may be sequentially disposed on a top surface of the electron transfer region 140.

According to embodiments of the present disclosure, the first layer 152, the second layer 154, and the third layer 156 may have work functions that may sequentially increase.

According to embodiments, the first layer 152 may include a rare earth oxide. The work function of the first layer 152 may be about 2 eV or more and less than about 3 eV. In some embodiments, the work function of the first layer 152 may be in a range from about 2.0 eV to 2.8 eV, from about 2.0 eV to 2.6 eV, from about 2.0 eV to 2.5 eV, or from about 2.0 eV to 2.4 eV, or from about 2.0 to 2.3 eV.

A material of the first layer 152 may be selected to satisfy the above-described work function range. According to embodiments, the first layer 152 may contain yttrium (Y) or ytterbium (Yb). The first layer 152 may include yttrium oxide (YOx) or ytterbium oxide (YbOx).

In some embodiments, the first layer 152 may include yttrium oxide (e.g., Y₂O₃).

A thickness of the first layer 152 may be in a range from about 5 Å to about 15 Å, from about 5 Å to about 13 Å, or from about 7 Å to about 12 Å.

The second layer 154 may include a material having improved electron injection properties. The second layer 154 may include an electride.

The work function of the second layer 154 may be in a range from about 3.0 eV to about 3.5 eV. In some embodiments, the work function of the second layer 154 may be in a range from about 3.0 eV to about 3.4 eV, from about 3.0 eV to about 3.3 eV, or from about 3.0 eV to about 3.2 eV.

A material of the second layer 154 may be selected to satisfy the above-described work function range. According to embodiments, the second layer 154 may include an electrode including a Group II metal element.

In some embodiments, the second layer 154 may include an electrode containing calcium and aluminum, and may include, for example, a C12A7 electrode. The C12A7 electrode may have the chemical formula 12CaO·7Al₂O₃. In an embodiment, the second layer 154 may include an amorphous calcium-aluminum-containing electride such as, for example, an amorphous C12A7 electride.

A thickness of the second layer 154 may be greater than the thickness of the first layer 152. For example, the thickness of the second layer 154 may be in a range from about 15 Å to about 30 Å, from about 15 Å to about 25 Å, or from about 17 Å to about 23 Å.

The second layer 154 may be substantially provided as an electron injection layer. Accordingly, in some embodiments, the electron injection layer 142 illustrated in FIG. 3 may be omitted, and the first layer 152 of the second electrode structure 150 may be directly formed on the electron transport layer 144.

The third layer 156 may include transparent conductive oxide (TCO), and may be provided as a second electrode or a cathode having a substantial conductivity. According to embodiments, the third layer 156 may include indium tin oxide (ITO), indium zinc oxide (IZO), indium tin oxide (ZnO), indium tin oxide (IGZO), or the like.

A work function of the third layer 156 may be in a range from about 4 eV to about 5 eV. For example, the work function of the third layer 156 may be in a range from about 4.0 eV to about 4.8 eV, from about 4.3 eV to about 4.8 eV, or from about 4.5 eV to about 4.8 eV.

A thickness of the third layer 156 may be greater than the thickness of the second layer 154. For example, the thickness of the third layer 156 may be in a range from about 100 Å to about 1,000 Å, from about 200 Å to about 800 Å, from about 200 Å to about 700 Å, or from about 300 Å to about 600 Å.

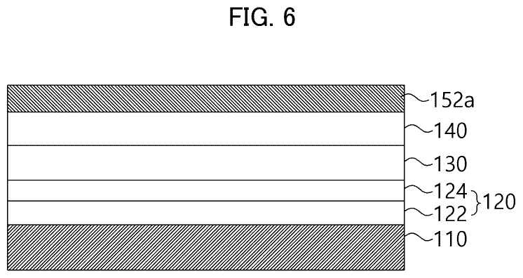

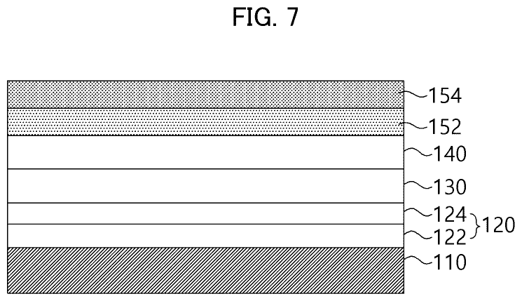

FIGS. 6 and 7 are schematic cross-sectional views illustrating a method of manufacturing a light emitting device according to embodiments.

Referring to FIG. 6, the hole transfer region 120 and the emission layer 130 may be formed on the first electrode 110. The electron transfer region 140 may be formed on the emission layer 130. In some embodiments, the hole transfer region 120 may be formed by sequentially forming the hole injection layer 122 and the hole transport layer 124 on the first electrode 110.

A rare earth metal layer 152a may be formed on a top surface of the electron transfer region 140 (e.g., the electron transport layer 144). According to embodiments, the rare earth metal layer 152a including yttrium (Y) and/or ytterbium (Yb) may be formed by a deposition process such as a sputtering process. The electron transfer region 140 or the electron transport layer 144 may be formed to include the above-described organic material.

Referring to FIG. 7, the second layer 154 may be formed on the rare earth metal layer 152a by a sputtering process using an electrode target.

According to embodiments, the second layer 154 including an amorphous calcium-aluminum-containing electride (e.g., an amorphous C12A7 electride) may be formed on the rare earth metal layer 152a using a target including a crystalline calcium-aluminum-containing electride (e.g., a crystalline C12A7 electride).

Oxygen may be injected into the rare earth metal layer 152a while forming the second layer 154 so that the rare earth metal layer 152a may be converted into the first layer 152 including a rare earth oxide such as Y₂O₃.

As described above, before forming the second layer 154 including the electride that has improved conductivity and electron injection properties, the rare earth metal layer 152a may be formed on the emission layer 130 or the electron transfer region 140. Accordingly, transfer of ion bombardment to the emission layer 130 or the electron transfer region 140 by the oxygen anion (O⁻) generated while forming the electride may be blocked or prevented.

Additionally, the first layer 152 may be formed using natural oxidation of the rare earth metal layer 152a. Thus, layer damage caused by oxygen diffusion into the emission layer 130 or the electron transfer region 140 may be prevented by a direct layer formation in the form of an oxide film. Further, the above-described sequential work function step structure may be efficiently maintained while suppressing work function fluctuations by the natural oxidation of the rare earth metal layer 152a.

Thereafter, the third layer 156 including the transparent conductive oxide may be formed on the second layer 154 by a deposition process such as a sputtering process.

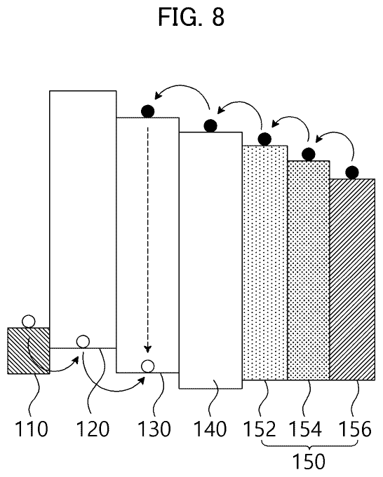

FIG. 8 is a schematic diagram illustrating a light-emitting mechanism in a light-emitting device according to embodiments.

Referring to FIG. 8, the second electrode structure 150 may be configured as a multi-layered cathode structure or an electron injection electrode structure. As described above, the work function may sequentially decrease in a direction of the third layer 156, the second layer 154, and the first layer 152. Accordingly, an electron injection barrier may be lowered by the first layer 152 while increasing electron injection efficiency by the third layer 156 and the second layer 154 having improved electron injection properties. Accordingly, sequential movement of an electron (indicated by a solid circle) to the electron transfer region 140 may be promoted.

Additionally, the second layer 154 may have improved hole blocking properties. Accordingly, in an embodiment, the hole blocking layer 146 illustrated in FIG. 4 may be omitted. Further, as described above, the electron injection layer 142 including, for example, the alkali metal and/or the alkaline earth metal may be omitted, and the second electrode structure 150 including the first layer 152, the second layer 154, and the third layer 156 may be directly formed on the electron transport layer 144 including the organic material.

An electron transferred from the electron transfer region 140 to the emission layer 130 may be combined with a hole (indicated by a hollow circle) generated in the first electrode 110 and moved to the emission layer 130 through the hole transfer region 120 to implement light emitting properties.

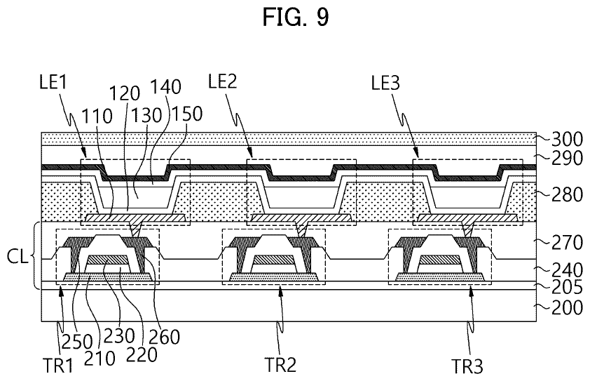

FIGS. 9 to 11 are schematic cross-sectional views illustrating display devices according to embodiments. For convenience of descriptions, a detailed stacked structure of the second electrode structure 150 is omitted in FIGS. 9 to 11.

Referring to FIG. 9, the display device may include a base substrate 200, a circuit layer CL disposed on the base substrate 200, and light-emitting devices (e.g., a first light-emitting device LE1, a second light-emitting device LE2, and a third light-emitting device LE3) disposed on the circuit layer CL.

The base substrate 200 may be configured as a supporting substrate or a back-plane substrate of an image display device. A glass substrate or a plastic substrate may be used as the base substrate 200.

In some embodiments, the base substrate 200 may include a polymer material having transparent and flexible properties. In this case, the base substrate 200 may be applied in a transparent flexible display device. For example, the base substrate 200 may include a polymer material such as polyimide, polysiloxane, an epoxy resin, an acrylic resin, polyester, etc. In an embodiment, the base substrate 200 may include polyimide.

The circuit layer CL may include transistors (e.g., a first transistor TR1, a second transistor TR2, and a third transistor TR3) and may be formed on the base substrate 200. The circuit layer may include wiring layers and insulation layers that form a thin film transistor array (TFT-Array).

The circuit layer CL may further include a buffer layer 205 on a top surface of the base substrate 200. The buffer layer 205 may block penetration of moisture through the base substrate 200, and may also block diffusion of impurities between the base substrate 200 and structures formed thereon.

The buffer layer 205 may include an inorganic insulating material such as silicon oxide, silicon nitride, or silicon oxynitride. The buffer layer 205 may include one of the aforementioned materials, or a combination thereof. In some embodiments, the buffer layer 205 may have a stacked structure including a silicon oxide layer and a silicon nitride layer.

The transistors (e.g., the first transistor TR1, the second transistor TR2, and the third transistor TR3) may be disposed on the buffer layer 205. A first transistor TR1, a second transistor TR2, and a third transistor TR3 among the transistors may be electrically connected to a first light-emitting device LE1, a second light-emitting device LE2 and a third light-emitting device LE3 among the light-emitting devices, respectively.

The transistors (e.g., the first transistor TR1, the second transistor TR2, and the third transistor TR3) may each include an active layer 210, a gate insulation layer 220, and a gate electrode 230.

The active layer 210 may be disposed on the buffer layer 205, and may be regularly and repeatedly patterned for each pixel by, for example, a photo-lithography process. The active layer 210 may include a silicon compound such as amorphous silicon or polysilicon. A p-type dopant or an n-type dopant may be doped in a region of the active layer 210, and the active layer 210 may include a source region, a drain region, and a channel region.

The active layer 210 may include an oxide semiconductor, such as indium gallium zinc oxide (IGZO), zinc tin oxide (ZTO), or ITZO.

The gate insulation layer 220 may be formed on the active layer 210, and the gate electrode 230 may be stacked on the gate insulation layer 220. As illustrated in FIG. 9, the gate insulation layer 220 may be patterned to partially cover each active layer 210. Alternatively, the gate insulation layer 220 may extend continuously over multiple pixels or light-emitting regions, and may be provided as a common layer for the first transistor TR1, the second transistor TR2, and the third transistor TR3.

The gate electrode 230 may overlap with the channel region of the active layer 210 in a vertical direction.

An insulating interlayer 240 covering the gate insulation layer 220 and the gate electrode 230 may be formed on the active layer 210. Connection electrodes 250 and 260, which may be in contact with or electrically connected to the active layer 210, may be disposed on the insulating interlayer 240.

The connection electrodes 250 and 260 may penetrate the insulating interlayer 240, and may be connected to the active layer 210. When the gate insulation layer 220 is formed continuously in common to a plurality of the light-emitting regions, the connection electrodes 250 and 260 may also penetrate the gate insulation layer 220 together.

The connection electrodes 250 and 260 may include a source electrode (e.g., the connection electrode 250) connected to or in contact with the source region of the active layer 210 and a drain electrode (e.g., the connection electrode 260) connected to or in contact with the drain region of the active layer 210.

The gate insulation layer 220 and the insulating interlayer 240 may include silicon oxide, silicon nitride, or silicon oxynitride, and may have a stacked structure including a silicon oxide layer and a silicon nitride layer.

The gate electrode 230 and the connection electrodes 250 and 260 may include a metal such as Ag, Mg, Al, W, Cu, Ni, Cr, Mo, Ti, Pt, Ta, Nd, Sc, or the like, an alloy thereof, or a nitride thereof.

A via insulation layer 270 may be formed on the insulating interlayer 240 to cover the connection electrodes 250 and 260.

The via insulation layer 270 may accommodate a via structure electrically connecting the first electrode 110 and the connection electrode 260 (e.g., the drain electrode) of the light-emitting device LE. The via insulation layer 270 may be configured as a planarization layer of the circuit layer CL. In some embodiments, the via insulation layer 270 may include an organic material such as polyimide, an epoxy resin, an acrylic resin, polyester, or the like.

The light-emitting devices (e.g., the first light-emitting device LE1, the second light-emitting device LE2, and the third light-emitting device LE3) may be disposed on the via insulation layer 270. For example, as described with reference to FIGS. 1 to 5, the light-emitting devices (e.g., the first light-emitting device LE1, the second light-emitting device LE2, and the third light-emitting device LE3) may include the first electrode 110, the hole transfer region 120, the emission layer 130, the electron transfer region 140, and the second electrode structure 150 which may be sequentially stacked on the via insulation layer 170. As described above, the second electrode structure 150 may include a stacked structure of the first layer 152, the second layer 154, and the third layer 156.

The first electrode 110 may be electrically connected to the transistors (e.g., the first transistor TR1, the second transistor TR2, and the third transistor TR3), or the connection electrodes 250 and 260 included in the circuit layer CL through the via structure. As illustrated in FIG. 9, the first electrode 110 may be in contact with or connected to the connection electrode 260 (e.g., the second drain electrode) to serve as a pixel electrode patterned for each light-emitting region or pixel region.

A pixel defining layer 280 may be formed on the via insulation layer 270 to define the light-emitting region or the pixel region. For example, a red light-emitting region, a green-light emitting region, and a blue light-emitting region may be separated and defined by the pixel defining layer 280, and the light-emitting devices (e.g., the first light-emitting device LE1, the second light-emitting device LE2, and the third light-emitting device LE3) may be a red light-emitting device, a green light-emitting device, and a blue light-emitting device, respectively.

The pixel defining layer 280 may partially cover the first electrode 110 of each light-emitting region.

As illustrated in FIG. 9, the hole transfer region 120 and the electron transfer region 140 may be commonly and continuously formed on the pixel defining layer 280 and a plurality of the first electrodes 110. The emission layer 130 may be formed in the form of an island pattern separated for each light-emitting region or pixel region, and may be limited by the pixel defining layer 280.

In some embodiments, the emission layer 130 may also be formed continuously and commonly across a plurality of the light-emitting regions or the pixel regions. In some embodiments, the hole transfer region 120, the emission layer 130, and the electron transfer region 140 may all be separated and selectively formed for each light-emitting region or pixel region.

The second electrode structure 150 may be continuously formed over a plurality of the light-emitting regions or the pixel regions, and may be provided as a common electrode structure.

A encapsulation layer 290 may be disposed on the pixel defining layer 280 and the light-emitting devices (e.g., the first light-emitting device LE1, the second light-emitting device LE2, and the third light-emitting device LE3) to protect the light-emitting devices (e.g., the first light-emitting device LE1, the second light-emitting device LE2, and the third light-emitting device LE3) from moisture or oxygen. The encapsulation layer 290 may be formed of a thin film encapsulation (TFE) having a single-layered structure or a multi-layered structure.

The encapsulation layer 290 may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE) or any combination thereof; or a combination of the inorganic layer and the organic layer.

The display device may further include a functional layer 300 disposed on the encapsulation layer 290. The functional layer 300 may include a sensor layer such as a touch sensor layer; or an optical layer such as a polarizing layer, a color conversion layer, or a color filter layer.

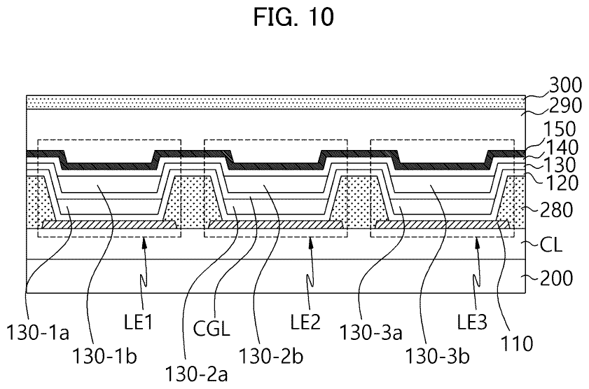

Referring to FIG. 10, each of the light emitting devices (e.g., the first light-emitting device LE1, the second light-emitting device LE2, and the third light-emitting device LE3) may have a tandem structure such as, for example, a 2-stack tandem structure.

In some embodiments, the hole transfer region 120 and the electron transfer region 140 may be continuously formed to be commonly included in the intermediate layer of each light-emitting structure. The charge generation layer CGL may also extend continuously across multiple pixels and may be commonly included in the intermediate layer of each light-emitting structure.

The first light emitting device LE1 may include a first lower emission layer 130-1a disposed between the hole transfer region 120 and the charge generation layer CGL, and a first upper emission layer 130-1b disposed between the charge generation layer CGL and the electron transfer region 140.

The second light-emitting device LE2 may include a second lower emission layer 130-2a disposed between the hole transfer region 120 and the charge generation layer CGL, and a second upper emission layer 130-2b disposed between the charge generation layer CGL and the electron transfer region 140.

The third light-emitting device LE3 may include a third lower emission layer 130-3a disposed between the hole transfer region 120 and the charge generation layer CGL, and a third upper emission layer 130-3b disposed between the charge generation layer CGL and the electron transfer region 140.

The lower and upper emission layers included in each light-emitting structure may generate a light of the same color as each other. In an embodiment, the first lower emission layer 130-1a and the first upper emission layer 130-1b included in the first light-emitting device LE1 may each be a red light emission layer. The second lower emission layer 130-2a and the second upper emission layer 130-2b included in the second light-emitting device LE2 may each be a green light emission layer. The third lower emission layer 130-3a and the third upper emission layer 130-3b included in the third light-emitting device LE3 may each be a blue light emission layer.

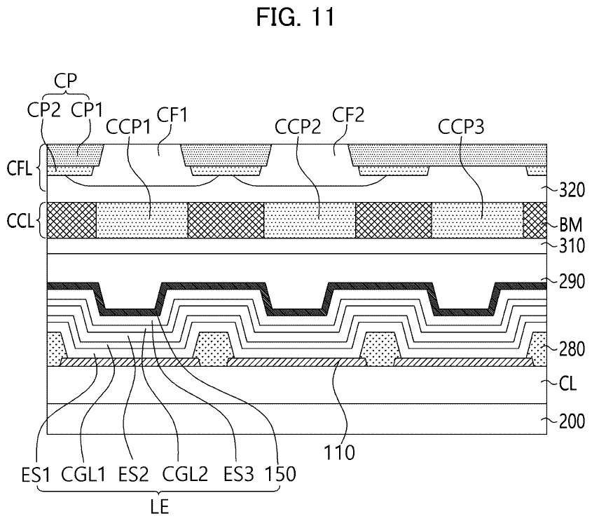

Referring to FIG. 11, the pixel defining layer 280 and the light-emitting device LE may be disposed on the circuit layer CL as described with reference to FIG. 9. According to embodiments, a light of the same wavelength region may be emitted for each pixel. In an embodiment, a blue light may be emitted from each light-emitting device LE.

In some embodiments, the light-emitting device having a tandem structure described with reference to FIG. 5 may be disposed in each light-emitting region. In this case, the intermediate layer ITL included in the light-emitting device LE may be commonly and continuously formed over a plurality of the light-emitting regions.

A color control layer CCL including color control portions (e.g., a first color control portion CCP1, a second color control portion CCP2, and a third color control portion CCP3) may be disposed on the encapsulation layer 290.

The color control portions (e.g., the first color control portion CCP1, the second color control portion CCP2, and the third color control portion CCP3) may include a light transformer such as a quantum dot or a phosphor. A wavelength of light introduced to each of the color control portions (e.g., the first color control portion CCP1, the second color control portion CCP2, and the third color control portion CCP3) may be converted by the light transformer and emitted. For example, the display device of FIG. 11 may be a quantum dot-organic light emitting diode (QD-OLED) display device.

The color control portions (e.g., the first color control portion CCP1, the second color control portion CCP2, and the third color control portion CCP3) may be separated or spaced apart from each other by a bank BM. The bank BM may substantially overlap with the pixel defining layer 280, and the color control portions (e.g., the first color control portion CCP1, the second color control portion CCP2, and the third color control portion CCP3) may substantially overlap with the emission layer 130.

The color control portions of the color control layer CCL may include a first color control portion CCP1 including a first quantum dot for converting a first color light provided from the light-emitting device LE into a second color light, a second color control unit CCP2 including a second quantum dot for converting the first color light into a third color light, and a third color control portion CCP3 for transmitting the first color light.

In some embodiments, the first color light, the second color light, and the third color light may be a blue light, a red light and a green light, respectively. The first quantum dot and the second quantum dot may be a red quantum dot and a green quantum dot, respectively.

The color control portions (e.g., the first color control portion CCP1, the second color control portion CCP2, and the third color control portion CCP3) may further include a scattering material such as inorganic particles. The third color control portion CCP3 may not include the quantum dot, and may include the scattering material. The scattering material may include TiO2, ZnO, Al₂O₃, SiO₂, hollow silica, or the like. These may be used alone or in a combination of two or more therefrom.

The color control portions (e.g., the first color control portion CCP1, the second color control portion CCP2, and the third color control portion CCP3) may further include a binder resin for dispersing the quantum dot and the scattering material. The binder resin may include an acrylic resin, a urethane resin, a silicone resin, an epoxy resin, or the like.

A color filter layer CFL including color filters and a light-shielding portion CP may be disposed on the color control layer CCL.

The color filter layer CFL may include a first color filter CF1 that transmits the second color light, a second color filter CF2 that transmits the third color light, and a third color filter that transmits the first color light. For example, the first color filter CF1 may be a red filter, the second color filter CF2 may be a green filter, and the third color filter may be a blue filter.

The first color filter CF1 and the second color filter CF2 may include a photosensitive binder resin, and a colorant including a pigment and/or dye. The first color filter CF1 may include a red pigment or dye, and the second color filter CF2 may include a green pigment or dye.

The light-shielding portion CP may be disposed between the color filters. In some embodiments, the light-shielding portion may include a first light-shielding portion CP1 and a second light-shielding portion CP2 including colorants of different colors from each other.

In some embodiments, the first light-shielding portion CP1 may include a blue colorant, and the second light-shielding portion CP2 may include a red colorant or a black color material. In an embodiment, in the blue light-emitting region, a portion of the first light-shielding portion CP1 exposed between the second light-shielding portions CP2 may be provided as a blue color filter, and an additional color filter (e.g., the third color filter) may be omitted.

A first barrier layer 310 may be disposed between the color control layer CCL and the light-emitting device LE (or the encapsulation layer 290). A second barrier layer 320 may be disposed between the color control layer CCL and the color filter layer CFL.

The first barrier layer 310 and the second barrier layer 320 may include at least one inorganic layer. For example, the first barrier layer 310 and the second barrier layer 320 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or the like.

The first barrier layer 310 and the second barrier layer 320 may have a multi-layered structure further including an organic layer.

In the display devices described with reference to FIGS. 9 to 11, the second electrode structure 150 having a multi-layered structure and a sequential stepped work function structure may be utilized to increase electron injection/transmission efficiency to the emission layer 130. Accordingly, overall luminous efficiency, color purity and luminance properties of the display device may be improved.

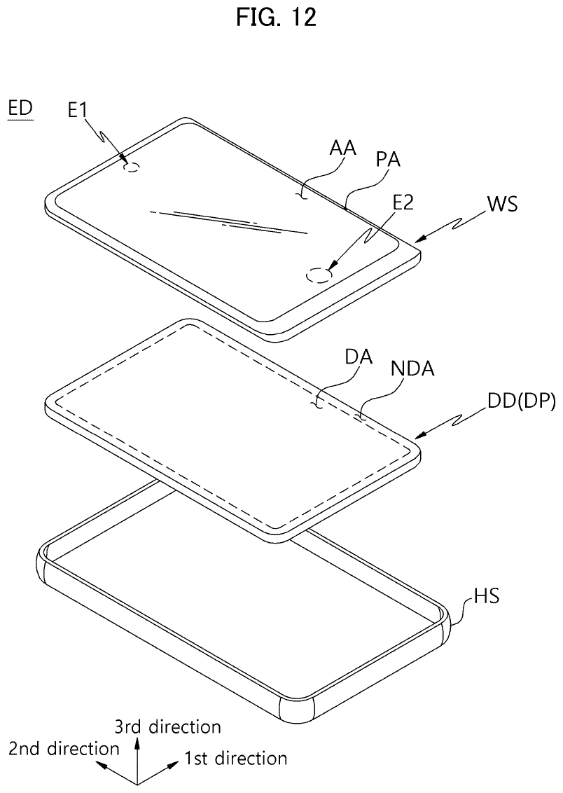

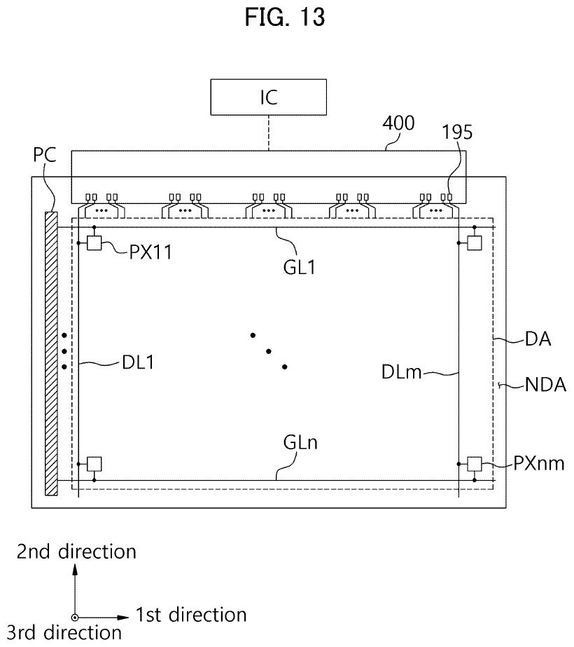

FIG. 12 is an exploded perspective view illustrating an electronic device according to embodiments. FIG. 13 is a schematic plan view illustrating an arrangement of pixels of a display device included in an electronic device according to embodiments.

In FIGS. 12 and 13, a first direction and a second direction may be two directions parallel to a display face of a window structure WS and/or a display panel DP, and perpendicular to each other. For example, the first direction may be an X-direction (a row direction) of a display device DD or the display panel DP, and the second direction may be a Y-direction (a column direction) of the display device DD or the display panel DP.

According to example embodiments, the electronic device may be implemented in the form of a mobile phone (e.g., a smart phone), a tablet, a PC, or the like, including the above-described display device.

Referring to FIG. 12, an electronic device ED may include the window structure WS, the display device DD, and a housing HS. The display device DD may include the display panel DP including the transistors and the light-emitting device LE as described above. The housing HS, the display device DD, and the window structure WS may be sequentially stacked in the third direction.

The window structure WS may provide an external display surface recognized by a user, such as a viewing surface of a mobile phone, and may include a transparent material film. For example, the window structure WS may include glass (e.g., ultra-thin glass (UTG), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

The display device DD and the display panel DP may have a display area DA and a non-display area NDA. The display area DA of the display panel DP may substantially correspond to or overlap with the active area AA of the window structure WS. The non-display area NDA of the display panel DP may substantially correspond to or overlap with the peripheral area PA of the window structure WS.

In some embodiments, functional device areas (e.g., a first functional device area E1 and a second functional device area E2) may be included in the active area AA of the window structure WS. For example, a first functional device area E1 may be included at one end portion of the active area AA and may be implemented, for example, in the form of a camera hole. The second functional device area E2 may be configured as a fingerprint sensing area.

For example, a sensor structure for a touch sensing or a fingerprint sensing may be disposed in the display panel DP or between the window structure WS and the display panel DP.

The housing HS may be configured as a frame structure or a rear housing of the display device DD or the electronic device ED. A cover panel may be disposed between the housing HS and the display panel DP. The housing HS or the cover panel may include a plate (e.g., an SUS plate) that supports the display panel DP, a printed circuit board 400 (see FIG. 13), or the like. The housing HS or the cover panel may include an elastic body for absorbing shock of the display device DD.

Referring to FIG. 13, a plurality of pixels PX11 to PXnm may be arranged in the display area DA of the display device DD or the display panel DP.

In example embodiments, a pixel circuit including scan lines GL1 to GLn (or gate lines) forming first to n^{th} rows and data lines DL1 to DLm forming first to m^{th} columns may be arranged on the base substrate 100 of the display device DD or the display panel DP. Each of the pixels PX11 to PXnm may be connected to a corresponding n^{th} row scan line among a plurality of scan lines GL1 to GLn and a corresponding m^{th} column data line among a plurality of data lines DL1 to DLm.

For example, the scan lines GL1 to GLn may be connected to the gate electrode 230 included in the transistors (e.g., the first transistor TR1, the second transistor TR2, and the third transistor TR3) (see FIG. 9). The data lines DL1 to DLm may be connected to, for example, the connection electrode 250 configured as the source electrode.

Each of the pixels PX11 to PXnm may further include the above-described pixel circuit and the light-emitting device LE. According to some embodiments, the pixel circuit may further include wirings such as a power line, a ground line, etc.

FIG. 13 illustrates that the data lines DL1 to DLm extend in the second direction and the scan lines GL1 to GLn extend in the first direction, but the configuration of the data lines and the gate lines is not limited to the configuration illustrated in FIG. 13.

A peripheral circuit PC may be disposed in the peripheral area PA of the electronic device DD or the non-display area NDA of the display panel DP. For example, the peripheral circuit PC may include a gate driving circuit. The gate driving circuit may be integrated into the display panel DP by an oxide semiconductor gate (OSG) driver circuit process, an amorphous silicon gate (OSG) driver circuit process, or a polysilicon gate (PSG) driver circuit process.

The electronic device DD may further include a printed circuit board 400. Pads 195 of the pixel circuit (e.g., the data lines) may be assembled at one end portion of the non-display area NDA. The printed circuit board 400 may be electrically connected to the pixel circuit through the pads 195. For example, the printed circuit board 400 may be electrically connected to the pads 195 by a heating-compression process using a conductive intermediate structure such as an anisotropic conductive film (ACF).

The pads 195 and a driving circuit element integrated circuit (IC) may be electrically connected through the printed circuit board 400. The driving circuit element IC may include an integrated circuit chip. In some embodiments, the integrated circuit chip may be mounted on the printed circuit board 400 in a chip-on-film (COF) form.

The driving circuit element IC may include a driving circuit of the display device DD and a driving circuit (e.g., an application processor chip) of the electronic device ED. The driving circuit element IC may further include a circuit board such as a main board on which a chip including the driving circuit is mounted.

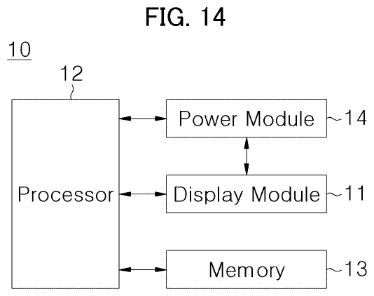

FIG. 14 is a block diagram of an electronic device in accordance with an embodiment.

Referring to FIG. 14, an electronic device 10 according to an embodiment may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

Data information for an operation of the processor 12 or the display module 11 may be stored in the memory 13. When the processor 12 executes an application stored in the memory 13, an image data signal, and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power for the operation of the electronic device 10.

At least one from among the components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13, and the power module 14 may be provided in the form of another device in the electronic device 10 different from the display device.

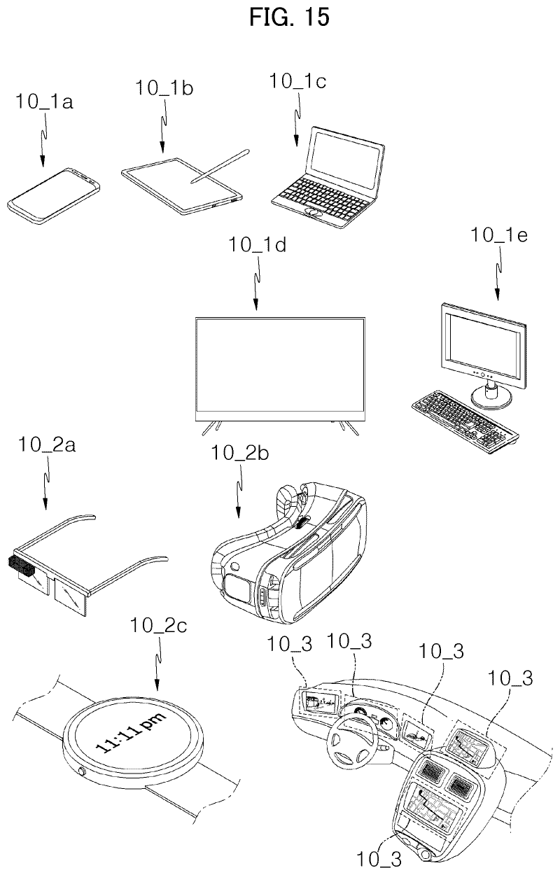

FIG. 15 is a schematic diagram of an electronic device in accordance with various embodiments.

Referring to FIG. 15, non-limiting examples of various electronic devices to which the display device according to the above-described embodiments may be applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a head-up display, a room mirror display, and the like. The electronic device may include a virtual reality glass or an augmented reality glass.

What is claimed is:

1. A light-emitting device, comprising:
a first electrode;
an intermediate layer on the first electrode, the intermediate layer comprising an emission layer; and
a second electrode structure comprising:
a first layer comprising a rare earth oxide;
a second layer comprising an electride; and
a third layer comprising a transparent conductive oxide,
wherein the intermediate layer is between the second electrode structure and the first electrode, and
wherein the first layer, the second layer, and the third layer are sequentially stacked on the intermediate layer.

2. The light-emitting device of claim 1, wherein a work function of the first layer, a work function of the second layer, and a work function of the third layer increase in the order of the first layer, the second layer, and the third layer.

3. The light-emitting device of claim 2, wherein the work function of the first layer is 2 eV or more, and less than 3 eV.

4. The light-emitting device of claim 2, wherein the work function of the second layer is in a range from 3.0 eV to 3.5 eV.

5. The light-emitting device of claim 2, wherein the work function of the third layer is in a range from 4 eV to 5 eV.

6. The light-emitting device of claim 1, wherein the first layer comprises yttrium (Y) oxide or ytterbium (Yb) oxide.

7. The light-emitting device of claim 1, wherein the electride of the second layer comprises a Group II metal element.

8. The light-emitting device of claim 7, wherein the electride of the second layer is an amorphous calcium-aluminum containing electride.

9. The light-emitting device of claim 1, wherein the third layer comprises indium tin oxide (ITO), indium zinc oxide(IZO), zinc oxide, indium gallium zinc oxide (IGZO), or indium tin zinc oxide (IGZO).

10. The light-emitting device of claim 1, wherein a thickness of the first layer, a thickness of the second layer, and a thickness of the third layer increase in the order of the first layer, the second layer, and the third layer.

11. The light-emitting device of claim 1, wherein the intermediate layer further comprises:
an electron transfer region between the emission layer and the second electrode structure; and
a hole transfer region between the emission layer and the first electrode.

12. The light-emitting device of claim 11, wherein the electron transfer region comprises an electron transport layer that comprises an organic material, and the first layer of the second electrode structure is in contact with the electron transport layer.

13. The light-emitting device of claim 1, wherein the first electrode is configured as an anode, and the third layer of the second electrode structure is configured as a cathode.

14. A display device, comprising:
a base substrate;
a pixel circuit comprising a transistor, the pixel circuit being on the base substrate; and
a light-emitting device connected to the transistor, wherein the light-emitting device comprises:
a first electrode;
an intermediate layer on the first electrode, the intermediate layer comprising an emission layer; and
a second electrode structure comprising:
a first layer comprising a rare earth oxide;
a second layer comprising an electride; and
a third layer comprising a transparent conductive oxide,
wherein the intermediate layer is between the second electrode structure and the first electrode, and
wherein the first layer, the second layer, and the third layer are sequentially stacked on the intermediate layer in the order of the first layer, the second layer, and the third layer.

15. An electronic device, comprising:
the display device of claim 14;
a memory; and
a processor configured to control an operation of the display device by executing data included in the memory.

16. The electronic device of claim 15, wherein the electronic device comprises virtual or augmented reality glasses, a smartphone, a tablet PC, a laptop, a TV, a desk monitor, smart glasses, a head mounted display, a smart watch, or a vehicle display.

17. A method for manufacturing a light-emitting device, the method comprising:
forming an intermediate layer on a first electrode, the intermediate layer including an emission layer;
forming a rare earth metal layer on the intermediate layer;
forming a second layer by depositing an electride on the rare earth metal layer while converting the rare earth metal layer into a first layer that comprises a rare earth oxide; and
forming a third layer on the second layer, the third layer including a transparent conductive oxide.

18. The method of claim 17, wherein the forming the second layer comprises naturally oxidizing the rare earth metal layer.

19. The method of claim 17, wherein the forming the second layer comprises performing a deposition process using a crystalline electride target, wherein the electride of the second layer is an amorphous electride.

20. The method of claim 17, wherein a work function of the first layer, a work function of the second layer, and a work function of the third layer increase in the order of the first layer, the second layer, and the third layer.
